(19) United States
(12) Patent Application Publication
(10) Pub. No.: US 2022/0244632 A1
(43) Pub. Date: Aug. 4, 2022

(54) FORMATION METHOD OF PHOTOMASK AND PHOTOMASK

(71) Applicant: CHANGXIN MEMORY TECHNOLOGIES, INC., Hefei City (CN)

(72) Inventor: Zhongqin ZHU, Hefei City (CN)

(21) Appl. No.: 17/477,822

(22) Filed: Sep. 17, 2021

Related U.S. Application Data
(63) Continuation of application No. PCT/CN2021/101940, filed on Jun. 24, 2021.

(30) Foreign Application Priority Data
Feb. 2, 2021 (CN) 202110141604.8

(51) Int. Cl. G03F 1/44; G03F 1/42

(52) U.S. Cl. CPC G03F 1/44; G03F 1/42

(57) ABSTRACT

Provided are a formation method of a photomask and a photomask. The formation method of a photomask comprises: providing a substrate, the substrate having chip regions, as well as a first scribe line and a second scribe line which are located on two opposite sides of the chip region; and forming a first set of marks in the first scribe line and forming a second set of marks in the second scribe line, the first set of marks comprising first sub-mark sets and first spaces which are alternately arranged along an extension direction of the first scribe line, the second set of marks comprising second sub-mark sets and second spaces which are alternately arranged along an extension direction of the second scribe line, the first sub-mark set and the second space being in alignment arrangement, the second sub-mark set and the first space being in alignment arrangement.

### CROSS-REFERENCE TO RELATED APPLICATIONS

The present disclosure is a continuation of International Patent Application No. PCT/CN2021/101940, filed Jun. 24, 2021, which claims priority to Chinese Patent Application No. 202110141604.8, entitled “FORMATION METHOD OF PHOTOMASK AND PHOTOMASK” and filed on Feb. 2, 2021. The entire contents of International Patent Application No. PCT/CN2021/101940 and Chinese Patent Application No. 202110141604.8 are incorporated herein by reference.

### TECHNICAL FIELD

The present disclosure relates to the field of semiconductor production technologies, and in particular to a formation method of a photomask and a photomask.

### BACKGROUND

Marks play a vital role in a semiconductor process. By measuring various marks, the quality of the process can be monitored to ensure product yield. In order to improve the utilization of silicon wafers, the marks are usually placed in a scribe line. With the continuous shrinking of technical nodes of the semiconductor process, a width of the scribe line becomes smaller and smaller direction during the development, which brings an unfriendly effect on the arrangement of marks on the scribe line. For example, for a scribe line with a width of 90 μm, a traditional mark arrangement method is adopted, and a set of marks can be placed symmetrically on both sides of the scribe line at an outer ring to meet the measurement requirements. However, when the width of the scribe line is reduced to 60 μm, the traditional two-sided symmetrical arrangement method is no longer applicable. For example, during an exposure process, the problem of mark overlapping will be caused.

Therefore, how to arrange marks in a narrow scribe line to improve the utilization rate of silicon wafers is a technical problem to be solved urgently.

### SUMMARY

Various embodiments of the present disclosure provide a formation method of a photomask and a photomask and are intended to solve a problem that marks cannot be placed in a narrow scribe line in a prior art.

According to some embodiments, one aspect of the present disclosure provides a formation method of a photomask, including the following steps:

providing a substrate, the substrate having chip regions, as well as a first scribe line and a second scribe line which are located on two opposite sides of the chip region; and

forming a first set of marks in the first scribe line and forming a second set of marks in the second scribe line, the first set of marks including first sub-mark sets and first spaces which are alternately arranged along an extension direction of the first scribe line, the second set of marks including second sub-mark sets and second spaces which are alternately arranged along an extension direction of the second scribe line, the first sub-mark set and the second space being in alignment arrangement, the second sub-mark set and the first space being in alignment arrangement.

According to some embodiments, another aspect of the present disclosure further provides a photomask, including:

a substrate, the substrate including chip regions, as well as a first scribe line and a second scribe line which are located on two opposite sides of the chip region;

a first set of marks, located in the first scribe line, the first set of marks including first sub-mark sets and first spaces which are alternately arranged along an extension direction of the first scribe line; and

a second set of marks formed in the second scribe line, the second set of marks including second sub-mark sets and second spaces which are alternately arranged along an extension direction of the second scribe line, the first sub-mark set and the second space being in alignment arrangement, the second sub-mark set and the first space being in alignment arrangement.

In the formation method of a photomask and the photomask according to the embodiments of the present disclosure, the first set of marks and the second set of marks are respectively formed in the first scribe line and the second scribe line on two opposite sides of the chip region, the first set of marks includes the first sub-mark sets and the first spaces which are alternately arranged along the extension direction of the first scribe line, the second set of marks includes the second sub-mark sets and the second spaces which are alternately arranged along the extension direction of the second scribe line, the first sub-mark set and the second space are in alignment arrangement, and the second sub-mark set and the first space are in alignment arrangement; in this way, even if the scribe lines are narrow, it can meet the requirement of forming a set of marks in each of the scribe lines on two opposite sides of the chip region, and ensure that the problem of mark overlapping can be avoided when the photomask is used for the photolithography process on a wafer.

### BRIEF DESCRIPTION OF DRAWINGS

FIG. 1 is a flowchart of a formation method of a photomask in an embodiment of the present disclosure;

FIGS. 2A to 2E are schematic diagrams of forming steps of a photomask in an embodiment;

FIG. 2F is a schematic diagram of an exposure unit (shown by a solid line) and an adjacent exposure unit (shown by a broken line) obtained by exposure of a photomask in this embodiment;

FIG. 2G is a schematic superposed diagram of a first set of marks and a second set of marks obtained by exposure of a photomask in this embodiment;

FIG. 2H is a schematic superposed diagram of a first set of marks and a second set of marks obtained by exposure of a photomask in another embodiment;

FIG. 2I is a schematic superposed diagram of a first set of marks and a second set of marks obtained by exposure of a photomask in yet another embodiment; and

FIG. 3 is a schematic diagram of a photomask in an embodiment of the present disclosure.

### DESCRIPTION OF EMBODIMENTS

The formation method of a photomask and the photomask according to the embodiments of the present disclosure will be described in detail below with reference to the accompanying drawings.

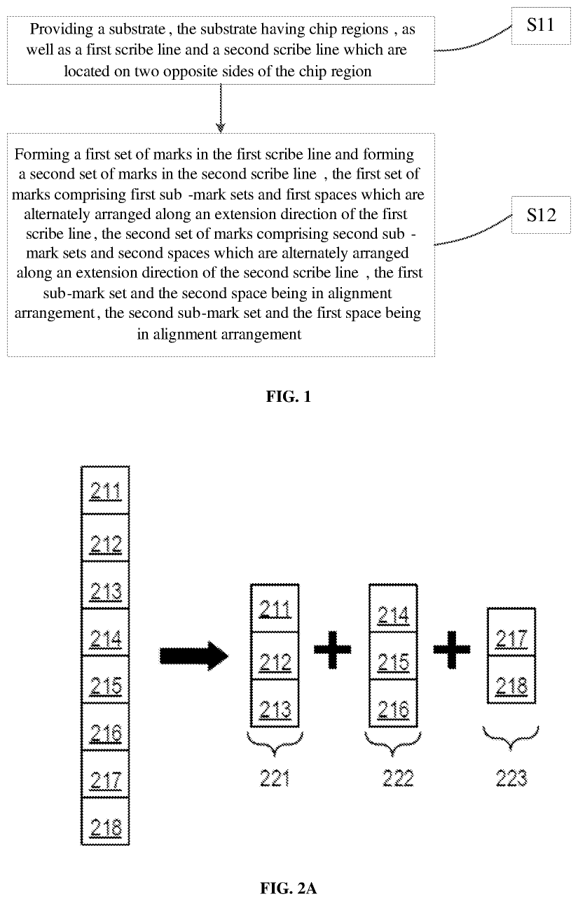

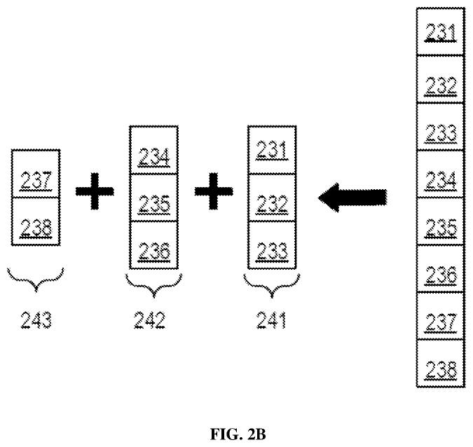

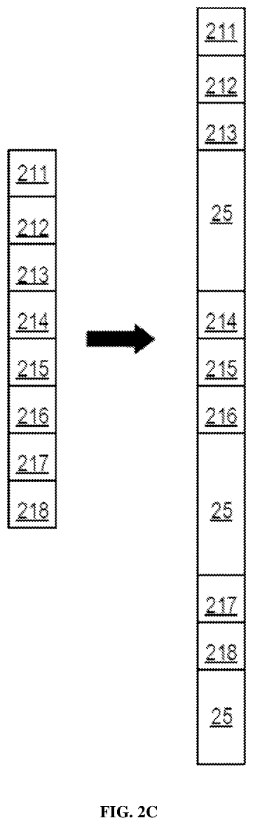

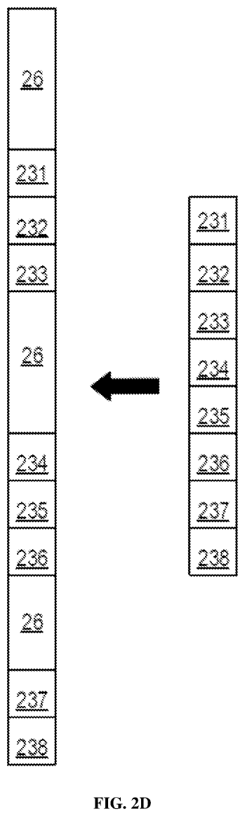

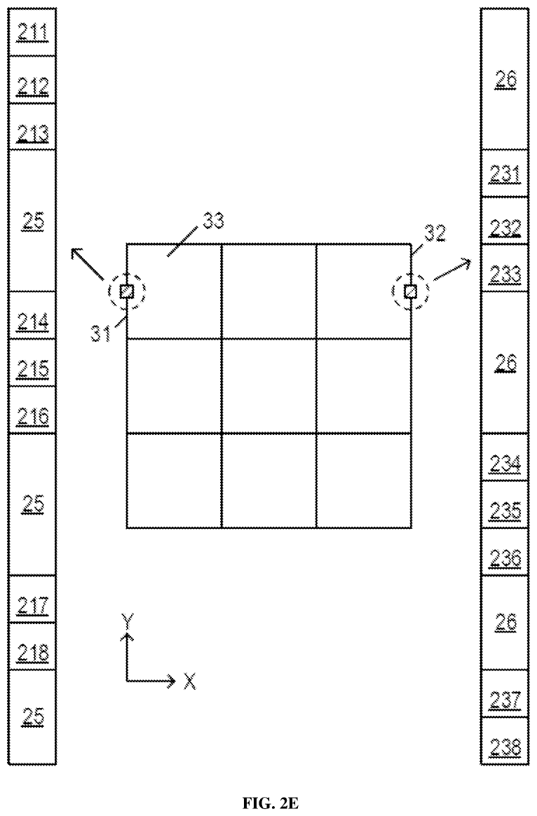

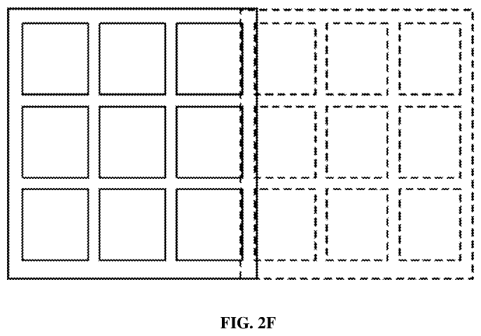

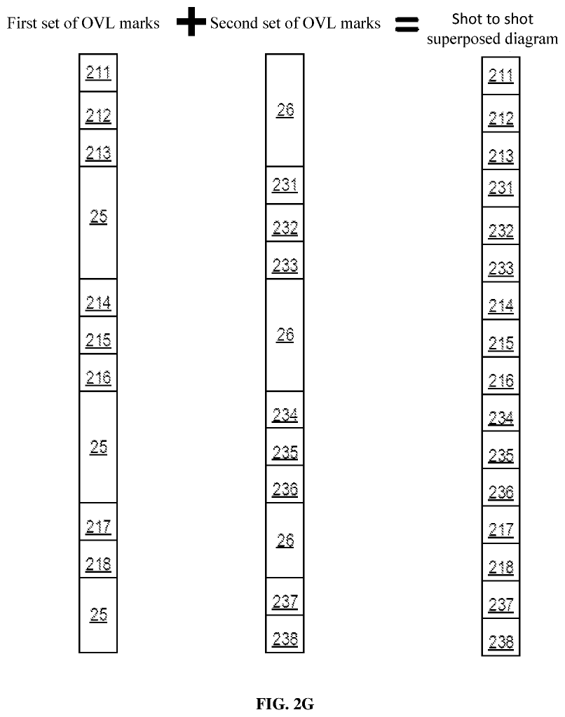

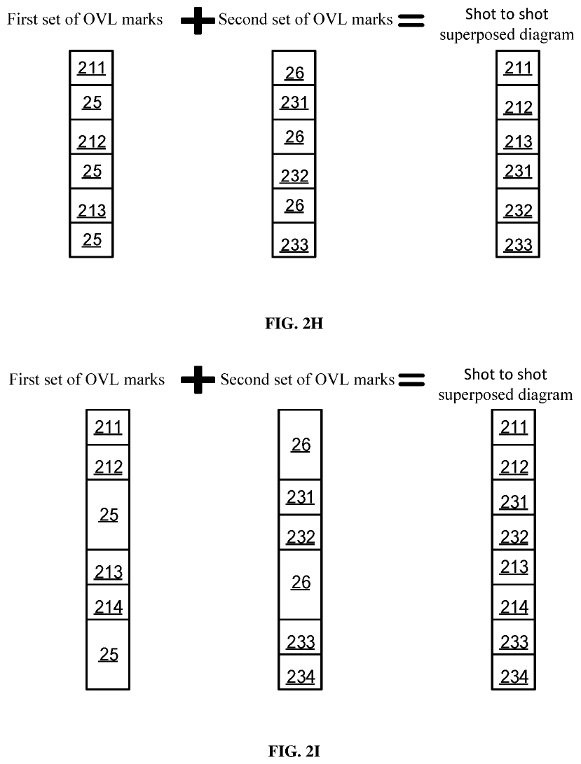

An embodiment of the present disclosure provides a formation method of a photomask. FIG. 1 is a flowchart of a formation method of a photomask in this embodiment, and FIGS. 2A to 2E are schematic diagrams of forming steps of a photomask in this embodiment. As shown in FIGS. 1 and 2A to 2E, the formation method of a photomask in this embodiment includes the following steps.

In step S11, a substrate is provided, and the substrate has chip regions 33, as well as a first scribe line 31 and a second scribe line 32 which are located on two opposite sides of the chip region 33.

As shown in FIG. 2E, a plurality of scribe lines are formed on the substrate, and the plurality of scribe lines respectively extend along an X-axis direction and a Y-axis direction, thereby dividing the substrate into a plurality of chip regions 33. Specifically, the substrate may serve as a glass substrate required for making a photomask. The glass substrate may be shaped like a rectangle or a square. The X-axis and the Y-axis may be the X-axis and the Y-axis in a rectangular coordinate system established with a center point of the glass substrate or any vertex of the glass substrate as a coordinate origin. The X-axis and the Y-axis may be respectively parallel to two adjacent sides of the rectangle or square. In this embodiment, the first scribe line 31 and the second scribe line 32 located on two opposite sides of the chip region 33 along the X-axis direction are taken as an example for description. The extension directions of the first scribe line 31 and the second scribe line 32 are parallel, and the first scribe line 31 or the second scribe line 32 may be adjacent to a single chip region 33 or they may be separated by a plurality of chip regions. In this embodiment, the first scribe line 31 and the second scribe line 32 both extend along the Y direction, and the first scribe line 31 and the second scribe line 32 are separated by three chip regions 33. The widths of the first scribe line 31 and the second scribe line 32 along the X-axis direction may be less than or equal to 60 μm.

In step S12, a first set of marks is formed in the first scribe line 31, and a second set of marks is formed in the second scribe line 32. The first set of marks includes first sub-mark sets and first spaces 25 which are alternately arranged along the extension direction of the first scribe line 31; the second set of marks includes second sub-mark sets and second spaces 26 which are alternately arranged along the extension direction of the second scribe line 32; the first sub-mark set and the second space 26 are in alignment arrangement, and the second sub-mark set and the first space 25 are in alignment arrangement. In an example, the first set of marks and the second set of marks are both over-engraved marks (OVL marks), and the OVL marks are configured to detect the alignment deviation between upper and lower layers in a photolithography process. The alignment arrangement can be understood as that projections of the first sub-mark set and the second space 26 in the extension direction of the first scribe line 31 or the second scribe line 32 at least partially overlap; for example, the projection of the first sub-mark set in the extension direction of the first scribe line 31 or the second scribe line 32 completely falls into the projection of the second space 26 in the extension direction of the first scribe line 31 or the second scribe line 32; or the projection of the second space 26 in the extension direction of the first scribe line 31 or the second scribe line 32 completely falls into the projection of the first sub-mark set in the extension direction of the first scribe line 31 or the second scribe line 32. Further, a bottom side of the first sub-mark set and a bottom side of the second space 26, or a top side of the first sub-mark set and a top side of the second space 26, or a center of the first sub-mark set and a center of the second space 26 are at the same position on the Y-axis. Specifically, the first sub-mark set and the second space 26 are both rectangles extending along the first scribe line 31 and the second scribe line 32 respectively; the rectangle has a bottom side, a top side, and a center, and both the first scribe line 31 and the second scribe line 32 extend along the Y-axis. Similarly, projections of the second sub-mark set and the first space 25 in the extension direction of the first scribe line 31 or the second scribe line 32 at least partially overlap; for example, the projection of the second sub-mark set in the extension direction of the first scribe line 31 or the second scribe line 32 completely falls into the projection of the first space 25 in the extension direction of the first scribe line 31 or the second scribe line 32; or the projection of the first space 25 in the extension direction of the first scribe line 31 or the second scribe line 32 completely falls into the projection of the second sub-mark set in the extension direction of the first scribe line 31 or the second scribe line 32. Further, a bottom side of the second sub-mark set and a bottom side of the first space 25, or a top side of the second sub-mark set and a top side of the first space 25, or a center of the second sub-mark set and a center of the first space 25 are at the same position on the Y-axis. Specifically, the second sub-mark set and the first space 25 are both rectangles extending along the second scribe line 32 and the first scribe line 31 respectively; the rectangle has a bottom side, a top side, and a center, and both the second scribe line 32 and the first scribe line 31 extend along the Y-axis. As shown in FIG. 2E, a dotted box on the first scribe line 31 in FIG. 2E indicates the first set of marks, and a dotted box on the second scribe line 32 indicates the second set of marks. Both the first scribe line 31 and the second scribe line 32 extend along the Y direction. The first set of marks includes three first sub-mark sets spaced apart and first spaces 25, and the first sub-mark sets are Set (211, 212, and 213), Set (214, 215, and 216), and Set (217, 218), respectively. The second set of marks includes three second sub-mark sets spaced apart and second spaces 26, and the second sub-mark sets are Set (231, 232, and 233), Set (234, 235, and 236), and Set (237 and 238), respectively. The projections of Set (211, 212, and 213), Set (214, 215 and 216) and Set (217 and 218) in the Y direction overlap with the projections of three second spaces 26 in the Y direction, respectively; and the projections of Set (231, 232 and 233), Set (234, 235 and 236) and Set (237 and 238) on the Y-axis overlap with the projections of the three first spaces 25 on the Y-axis, respectively. FIG. 2E is only a schematic representation of the relative positional relationship between the first set of marks and the second set of marks. In an actual process, the first set of marks is located inside the first scribe line 31 and the second set of marks is located inside the second scribe line 32.

In some embodiments, the step of forming the first set of marks in the first scribe line 31 and forming the second set of marks in the second scribe line 32 specifically includes:

providing a first set of initial marks and a second set of initial marks, the first set of initial marks including a plurality of first sub-marks continuously arranged along the extension direction of the first scribe line 31, the second set of initial marks including a plurality of second sub-marks continuously arranged along the extension direction of the second scribe line 32;

splitting the first set of initial marks to form a plurality of first sub-mark sets, each of the first sub-mark sets including several first sub-marks, as shown in FIG. 2A;

combining the plurality of first sub-mark sets and the plurality of first spaces 25 to form the first set of marks including the first sub-mark sets and the first spaces 25 which are alternately arranged along the extension direction of the first scribe line 31, as shown in FIG. 2C;

splitting the second set of initial marks to form a plurality of second sub-mark sets, each of the second sub-mark sets including several second sub-marks, as shown in FIG. 2B;

combining the plurality of second sub-mark sets and the plurality of second spaces 26 to form the second set of marks including the second sub-mark sets and the second spaces 26 which are alternately arranged along the extension direction of the second scribe line 32, as shown in FIG. 2D; and

forming the first set of marks in the first scribe line 31 and forming the second set of marks in the second scribe line 32, so that the first sub-mark set is aligned with the second space and the second sub-mark set is aligned with the first space, as shown in FIG. 2E.

In the description of the present disclosure, “a plurality of” means two or more. The following description is given by an example where the first set of initial marks includes eight first sub-marks and the second set of initial marks includes eight second sub-marks. As shown in FIG. 2A, the first set of initial marks includes eight first sub-marks (respectively denoted by reference numerals 211, 212, 213, 214, 215, 216, 217, and 218); the first set of initial marks is split into a plurality of first sub-mark sets (respectively denoted by reference numerals 221, 222, and 223). As shown in FIG. 2B, the second set of initial marks includes eight second sub-marks (respectively denoted by reference numerals 231, 232, 233, 234, 235, 236, 237, and 238); the second set of initial marks is split into a plurality of second sub-mark sets (respectively denoted by reference numerals 241, 242, and 243). The first scribe line 31 and the second scribe line 32 are parallel to each other, and both extend along the Y-axis direction. A plurality of first spaces 25 are provided, and the plurality of first sub-mark sets and the plurality of first spaces 25 are combined to form a first set of marks including the first sub-mark sets and the first spaces 25 which are alternately arranged along the extension direction of the first scribe line 31, as shown in FIG. 2C. A plurality of second spaces 26 are provided, and the plurality of second sub-mark sets and the plurality of second spaces 26 are combined to form a second set of marks including the second sub-mark sets and the second spaces 26 which are alternately arranged along the extension direction of the second scribe line 32, as shown in FIG. 2D. Finally, the first set of marks is formed in the first scribe line 31 and the second set of marks is formed in the second scribe line 32, so that the first sub-mark set is aligned with the second space and the second sub-mark set is aligned with the first space, as shown in FIG. 2E. The first space 25 refers to a blank region between two adjacent first sub-mark sets, and the second space 26 refers to a blank region between two adjacent second sub-mark sets.

FIG. 2F is a schematic diagram of an exposure unit (shown by a solid line) and an adjacent exposure unit (shown by a broken line) obtained by exposure of a photomask in this embodiment. Since the first sub-mark set is aligned with the second space and the second sub-mark set is aligned with the first space, that is, the first sub-mark set and the second sub-mark set are arranged in a misaligned manner. Therefore, the resulting superposed image, as shown in FIG. 2G, does not have the problem that the first set of marks overlaps with the second set of marks.

In some embodiments, the first set of initial marks is the same as the second set of initial marks.

In other embodiments, those skilled in the art can also set a shape of the first sub-mark in the first set of initial marks and a shape of the second sub-mark in the second set of initial marks according to actual needs, so that the first set of initial marks is different from the second set of initial marks.

In some embodiments, any two of the first sub-mark sets are the same in the number of first sub-mark therein; or, there are two first sub-mark sets which are different in the number of first sub-mark therein.

Specifically, in the process of splitting the first set of initial marks, the plurality of first sub-mark sets may be set to be the same or different in the number of first sub-marks therein according to actual needs. Similarly, in the process of splitting the second set of initial marks, the plurality of second sub-mark sets may be set to be the same or different in the number of second sub-marks therein according to actual needs. In this embodiment, the eight first sub-marks are divided into three first sub-mark sets; two of the first sub-mark sets (denoted by reference numerals 221 and 222) each include three first sub-marks and the other first sub-mark set (denoted by the reference numeral 223) includes two first sub-marks. In this embodiment, the eight second sub-marks are divided into three second sub-mark sets; two of the second sub-mark sets (denoted by reference numerals 241 and 242) each include three second sub-marks and the other second sub-mark set (denoted by the reference numeral 243) includes two second sub-marks. The smaller the number of first sub-mark sets or second sub-mark sets, the smaller the corresponding number of first spaces 25 or second spaces 26, the more helpful it is to control a relative positional relationship between the first set of marks and the second set of marks (e.g., an alignment relationship between the first sub-mark set and the second space and an alignment relationship between the second sub-mark set and the first space).

In other embodiments, each first sub-mark set also may include one or two first sub-mark, and each second sub-mark set may include one or two second sub-mark. As shown in FIG. 2H, each first sub-mark set includes one first sub-mark (that is, there is a first space between two adjacent first sub-marks), and each second sub-mark set includes one second sub-mark (that is, there is a second space between two adjacent second sub-marks); as shown in FIG. 2I, each first sub-mark set includes two first sub-marks (that is, a first space is arranged every two first sub-marks), and each second sub-mark set includes two second sub-marks (that is, a second space is arranged every two second sub-marks).

In some embodiments, any two of the first sub-mark sets are different in the shape of the first sub-marks therein.

In some embodiments, a length of one of the first sub-mark sets along the extension direction of the first scribe line 31 is less than or equal to that of one of the second spaces 26 aligned therewith in the extension direction of the second scribe line 32;

a length of one of the second sub-mark sets along the extension direction of the second scribe line 32 is less than or equal to that of one of the first spaces 25 aligned therewith in the extension direction of the first scribe line 31.

Specifically, the length of one of the first sub-mark sets along the Y-axis direction is less than or equal to the length of the second space 26 aligned therewith in the Y-axis direction, and the length of one of the second sub-mark sets along the Y-axis direction is less than or equal to that of one of the first space 25 aligned therewith in the Y-axis direction, thereby avoiding the problem that the first set of marks overlaps with the second set of marks during the photolithography process.

In some embodiments, in a direction toward the second scribe line 32 along the first scribe line 31, a width of the first sub-mark, a width of the first space 25, a width of the second sub-mark, and a width of the second space 26 are all equal.

Specifically, along the X-axis direction, the width of the first sub-mark, the width of the first space 25, the width of the second sub-mark, and the width of the second space 26 are all equal, which simplifies the manufacturing process and also helps to improve the accuracy of exposure.

In some embodiments, the number and shape of the first sub-marks in each of the first sub-mark sets are the same as the number and shape of the second sub-marks in the corresponding second sub-mark set. Specifically, the numbers of first sub-mark sets and the number of first spaces 25 are the same as the number of second spaces 26 and the number of second sub-mark sets respectively, and the number and shape of the first sub-marks in each first sub-mark set are the same as the number and shape of the second sub-marks in the corresponding second sub-mark set. The second sub-mark set corresponding to the first sub-mark set can be understood as that the first sub-mark set corresponds to the second sub-mark set aligned with the first space 25 adjacent to the first sub-mark set. Specifically, as shown in FIG. 2E, the number and shape of the first sub-marks (respectively denoted by the reference numerals 211, 212 and 213) in the first sub-mark set are the same as those of the second sub-marks (respectively denoted by the reference numerals 231, 232 and 233) in the second sub-mark set aligned with the first space 25 under and adjacent to the first sub-mark set. For example, the first sub-mark set and the second sub-mark set each include three sub-marks, and the first sub-marks 211, 212 and 213 are OVL marks Bar-in-Bar, AIM, and Box-in-Box, respectively; correspondingly, the second sub-marks 231, 232 and 233 are also the OVL marks Bar-in-Bar, AIM, and Box-in-Box, respectively. The number and shape of the first sub-marks (respectively denoted by the reference numerals 234, 235 and 236) in the first sub-mark set are the same as those of the second sub-marks (respectively denoted by the reference numerals 217 and 218) in the second sub-mark set aligned with the first space 25 under and adjacent to the first sub-mark set. In this way, it can be ensured that the detection conditions of adjacent exposure units are as consistent as possible during exposure, thereby reducing the detection deviation caused by the arrangement positions of the OVL marks.

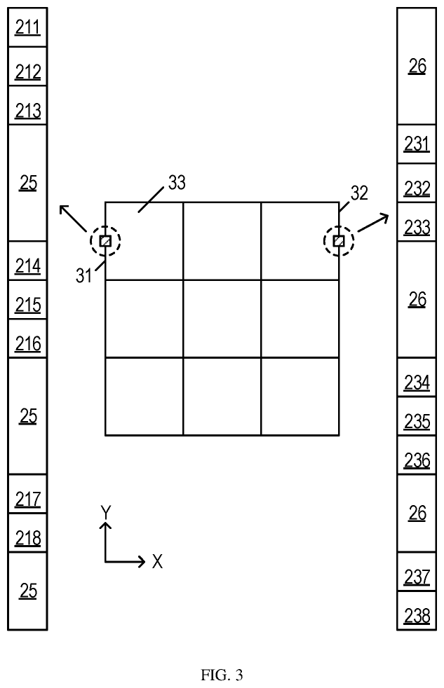

Moreover, this embodiment further provides a photomask. FIG. 3 is a schematic diagram of a photomask in an embodiment of the present disclosure. The marks in the photomask according to this embodiment can be formed by the methods shown in FIGS. 1 and 2A to 2E. As shown in FIGS. 3, the photomask in this embodiment includes:

a substrate, the substrate having chip regions 33, as well as a first scribe line 31 and a second scribe line 32 which are located on two opposite sides of the chip region 33;

a first set of marks, formed in the first scribe line 31, the first set of marks including first sub-mark sets and first spaces 25 which are alternately arranged along an extension direction of the first scribe line 31; and

a second set of marks formed in the second scribe line 32, the second set of marks including second sub-mark sets and second spaces 26 which are alternately arranged along an extension direction of the second scribe line 32, the first sub-mark set and the second space 26 being in alignment arrangement, the second sub-mark set and the first space 25 being in alignment arrangement.

In some embodiments, the first set of marks includes a plurality of first sub-mark sets, and each of the first sub-mark sets includes several first sub-marks;

any two of the first sub-mark sets are the same in the number of first sub-mark therein; or, there are two first sub-mark sets which are different in the number of first sub-mark therein.

In some embodiments, any two of the first sub-mark sets are different in the shape of the first sub-marks therein.

In some embodiments, a length of one of the first sub-mark sets along the extension direction of the first scribe line 31 is less than or equal to that of one of the second spaces 26 aligned therewith in the extension direction of the second scribe line 32;

a length of one of the second sub-mark sets along the extension direction of the second scribe line 32 is less than or equal to that of one of the first spaces 25 aligned therewith in the extension direction of the first scribe line 31.

In some embodiments, the first set of marks includes a plurality of first sub-mark sets, and each of the first sub-mark sets includes several first sub-marks;

the second set of marks includes a plurality of second sub-mark sets, and each of the second sub-mark sets includes several second sub-marks;

in a direction along the first scribe line and toward the second scribe line, a width of the first sub-mark, a width of the first space 25, a width of the second sub-mark, and a width of the second space 26 are all equal.

In some embodiments, there is at least one first sub-mark set having the first sub-marks of the same number and shape as the second sub-marks in one of the second sub-mark sets.

In some embodiments, the number and shape of the first sub-marks in each of the first sub-mark sets are the same as the number and shape of the second sub-marks in the corresponding second sub-mark set.

In the formation method of a photomask and the photomask in this embodiment, the first set of marks and the second set of marks are respectively formed in the first scribe line and the second scribe line on two opposite sides of the chip region, the first set of marks includes first sub-mark sets and first spaces which are alternately arranged along the extension direction of the first scribe line, the second set of marks includes second sub-mark sets and second spaces which are alternately arranged along the extension direction of the second scribe line, the first sub-mark set and the second space are in alignment arrangement, and the second sub-mark set and the first space are in alignment arrangement; in this way, even if the scribe lines are narrow, it can meet the requirement of forming a set of marks in each of the scribe lines on two opposite sides of the chip region, and ensure that the problem of mark overlapping can be avoided when the photomask is used for the photolithography process on a wafer.

The above are only some embodiments of the present disclosure. It should be noted that for those of ordinary skill in the art, without departing from the principle of the present disclosure, several improvements and modifications can be made, and these improvements and modifications also should be considered as falling within the protection scope of the present disclosure.

What is claimed is:

1. A formation method of a photomask, comprising:
providing a substrate, the substrate having chip regions, as well as a first scribe line and a second scribe line which are located on two opposite sides of the chip region; and
forming a first set of marks in the first scribe line and forming a second set of marks in the second scribe line, the first set of marks comprising first sub-mark sets and first spaces which are alternately arranged along an extension direction of the first scribe line, the second set of marks comprising second sub-mark sets and second spaces which are alternately arranged along an extension direction of the second scribe line, the first sub-mark set and the second space being in alignment arrangement, the second sub-mark set and the first space being in alignment arrangement.

2. The formation method of a photomask according to claim 1, wherein the forming the first set of marks in the first scribe line and forming the second set of marks in the second scribe line specifically comprises: providing a first set of initial marks and a second set of initial marks, the first set of initial marks comprising a plurality of first sub-marks continuously arranged along the extension direction of the first scribe line, the second set of initial marks comprising a plurality of second sub-marks continuously arranged along the extension direction of the second scribe line;
splitting the first set of initial marks to form a plurality of first sub-mark sets, each of the first sub-mark sets comprising several of the first sub-marks;
combining the plurality of first sub-mark sets and the first spaces to form the first set of marks comprising the first sub-mark sets and the first spaces which are alternately arranged along the extension direction of the first scribe line;
splitting the second set of initial marks to form a plurality of second sub-mark sets, each of the second sub-mark sets comprising several of the second sub-marks;
combining the plurality of second sub-mark sets and the second spaces to form the second set of marks comprising the second sub-mark sets and the second spaces which are alternately arranged along the extension direction of the second scribe line; and
forming the first set of marks in the first scribe line and forming the second set of marks in the second scribe line, so that the first sub-mark set is aligned with the second space and the second sub-mark set is aligned with the first space.

3. The formation method of a photomask according to claim 2, wherein any two of the first sub-mark sets are the same in the number of first sub-mark therein; or, there are two first sub-mark sets which are different in the number of first sub-mark therein.

4. The formation method of a photomask according to claim 2, wherein any two of the first sub-mark sets are different in the shape of the first sub-marks therein.

5. The formation method of a photomask according to claim 2, wherein a length of one of the first sub-mark sets along the extension direction of the first scribe line is less than or equal to that of one of the second spaces aligned therewith in the extension direction of the second scribe line;
a length of one of the second sub-mark sets along the extension direction of the second scribe line is less than or equal to that of one of the first spaces aligned therewith in the extension direction of the first scribe line.

6. The formation method of a photomask according to claim 2, wherein in a direction along the first scribe line and toward the second scribe line, a width of the first sub-mark, a width of the first space, a width of the second sub-mark, and a width of the second space are all equal.

7. The formation method of a photomask according to claim 2, wherein the first set of initial marks is the same as the second set of initial marks.

8. The formation method of a photomask according to claim 2, wherein the number and shape of the first sub-marks in each of the first sub-mark sets are the same as the number and shape of the second sub-marks in the corresponding second sub-mark set.

9. A photomask, comprising:
a substrate, the substrate including chip regions, as well as a first scribe line and a second scribe line which are located on two opposite sides of the chip region;
a first set of marks, located in the first scribe line, the first set of marks comprising first sub-mark sets and first spaces which are alternately arranged along an extension direction of the first scribe line; and
a second set of marks formed in the second scribe line, the second set of marks comprising second sub-mark sets and second spaces which are alternately arranged along an extension direction of the second scribe line, the first sub-mark set and the second space being in alignment arrangement, the second sub-mark set and the first space being in alignment arrangement.

10. The photomask according to claim 9, wherein the first set of marks comprises a plurality of first sub-mark sets, and each of the first sub-mark sets comprises several first sub-marks;
any two of the first sub-mark sets are the same in the number of first sub-mark therein; or, there are two first sub-mark sets which are different in the number of first sub-mark therein.

11. The photomask according to claim 10, wherein any two of the first sub-mark sets are different in the shape of the first sub-marks therein.

12. The photomask according to claim 9, wherein a length of one of the first sub-mark sets along the extension direction of the first scribe line is less than or equal to that of one of the second spaces aligned therewith in the extension direction of the second scribe line;
a length of one of the second sub-mark sets along the extension direction of the second scribe line is less than or equal to that of one of the first spaces aligned therewith in the extension direction of the first scribe line.

13. The photomask according to claim 9, wherein the first set of marks comprises a plurality of first sub-mark sets, and each of the first sub-mark sets comprises several first sub-marks;
the second set of marks comprises a plurality of second sub-mark sets, and each of the second sub-mark sets comprises several second sub-marks;
in a direction along the first scribe line and toward the second scribe line, a width of the first sub-mark, a width of the first space, a width of the second sub-mark, and a width of the second space are all equal.

14. The photomask according to claim 13, wherein there is at least one first sub-mark set having the first sub-marks of the same number and shape as the second sub-marks in one of the second sub-mark sets.

15. The photomask according to claim 14, wherein the number and shape of the first sub-marks in each of the first sub-mark sets are the same as the number and shape of the second sub-marks in the corresponding second sub-mark set.
